(19) United States
(12) Patent Application Publication
(10) Pub. No.: US 2025/0212664 A1
(43) Pub. Date: Jun. 26, 2025

(54) Organic Light Emitting Display Device

(71) Applicant: LG Display Co., Ltd., Seoul (KR)

(72) Inventor: SungHee Kim, Paju-si (KR)

(21) Appl. No.: 18/790,747

(22) Filed: Jul. 31, 2024

(30) Foreign Application Priority Data
Dec. 20, 2023 (KR) 10-2023-0187548

(51) Int. Cl. H10K 59/80; H10K 59/126; H10K 59/40

(52) U.S. Cl. CPC H10K 59/8791; H10K 59/126; H10K 59/40; H10K 59/873; H10K 59/879

(57) ABSTRACT

An organic light emitting display device presented herein includes a substrate, a plurality of light emitting diodes on the substrate, an encapsulation layer that covers the plurality of light emitting diodes, a gas blocking layer on the encapsulation layer, the gas blocking layer having a curing rate of 90% or higher, and a polarizer on the gas blocking layer, a bottom surface of the polarizer in direct contact with the gas blocking layer. The organic light emitting display device features suppressed deformation and discoloration of the polarizer by blocking outgas generated from organic materials.

### CROSS-REFERENCE TO RELATED APPLICATION

This application claims the priority of Republic of Korea Patent Application No. 10-2023-0187548, filed on Dec. 20, 2023, which is hereby incorporated by reference in its entirety.

### BACKGROUND

### Field

The present disclosure relates to an organic light emitting display device, and more particularly, to an organic light emitting display device which suppresses degradation of a polarizer in a high temperature/high humidity environment.

### Description of Related Art

A display device may be used for various types of devices, such as TVs, monitors, tablet computers, navigations, game consoles, and mobile phones. As such a display device, various types of display devices, such as a liquid crystal display (LCD) device or an organic light emitting display (OLED) device, have been used.

Among various display devices, the organic light emitting display device does not require a separate light source. Therefore, the organic light emitting display device can be manufactured to be light and thin and has process advantages and has low power consumption in accordance with the low voltage driving. Further, the organic light emitting display device includes a self-emitting element and includes layers formed of organic thin films so that the flexibility and elasticity are superior to the other display devices, and it can be designed in various shapes.

Generally, in order to suppress the deterioration of visibility and a contrast ratio due to light which is incident from the outside into the display device, in the organic light emitting display device, a polarizer is disposed on a display panel.

### SUMMARY

Generally, the polarizer of the organic light emitting display device includes a polarization film formed of polyvinyl alcohol (PVA) processed with iodine. In a high temperature/high humidity environment, outgas, such as acid, is generated from an organic material layer disposed below the polarizer to permeate the polarizer. Such an acid component generates hydrogen ions, and the hydrogen ions react with polyvinyl alcohol of the polarization film. Polyvinyl alcohol is deformed into polyene containing a plurality of double bonds by hydrogen ions. As described above, as the number of double bonds is increased, an absorption wavelength of the polarizer shifts from the UV wavelength band to the visible ray wavelength band, which results in the reduction of the transmittance. Further, when the polyene was generated, there was a problem in that a reddish phenomenon that the polarizer is discolored to red has occurred.

Specifically, when the glass is used as a cover member, heat transfer is easy and moisture discharge is difficult, which can further accelerate the formation of polyene from acid polyvinyl alcohol.

Accordingly, a technology was proposed to suppress deformation into polyene by adding a crosslinking agent to polyvinyl alcohol to increase the degree of cross-linking. In this case, the reddish phenomenon due to the outgas was improved, but there were problems in that the effect was insignificant and after image was generated during the non-driving state.

Accordingly, an object to be achieved by the present disclosure is to suppress the deformation and discoloration of the polarizer by blocking outgas generated from organic materials.

Objects of the present disclosure are not limited to the above-mentioned objects, and other objects, which are not mentioned above, can be clearly understood by those skilled in the art from the following descriptions.

According to one or more embodiments of the present disclosure, an organic light emitting display device includes a substrate; a plurality of light emitting diodes on the substrate; an encapsulation layer that covers the plurality of light emitting diodes; a gas blocking layer on the encapsulation layer, the gas blocking layer having a curing rate of 90% or higher; and a polarizer on the gas blocking layer, a bottom surface of the polarizer in direct contact with the gas blocking layer.

Other detailed matters of the embodiments of the present disclosure are included in the detailed description and the drawings.

According to one or more embodiments the present disclosure, the organic light emitting display device includes a gas blocking layer that blocks an outgas generated from the organic material in the high temperature/high humidity environment. Therefore, the deformation of the polymer of the polarizer into the polyene due to the outgas may be suppressed and the reddish phenomenon and transmittance degradation of the polarizer may be suppressed.

The effects according to embodiments of the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a cross-sectional view of a display device according to an embodiment of

the present disclosure;

FIG. 2 is a cross-sectional view of a polarizer according to an embodiment of the present disclosure;

FIG. 3 is a cross-sectional view of a display device according to another embodiment of the present disclosure;

FIG. 4 is a cross-sectional view of a display device according to still another embodiment of the present disclosure; and

FIG. 5 is a graph illustrating a degree of occurrence of a reddish phenomenon according to a temperature of a specimen according to Comparative Embodiment, Reference Embodiment, and Embodiment 1 according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

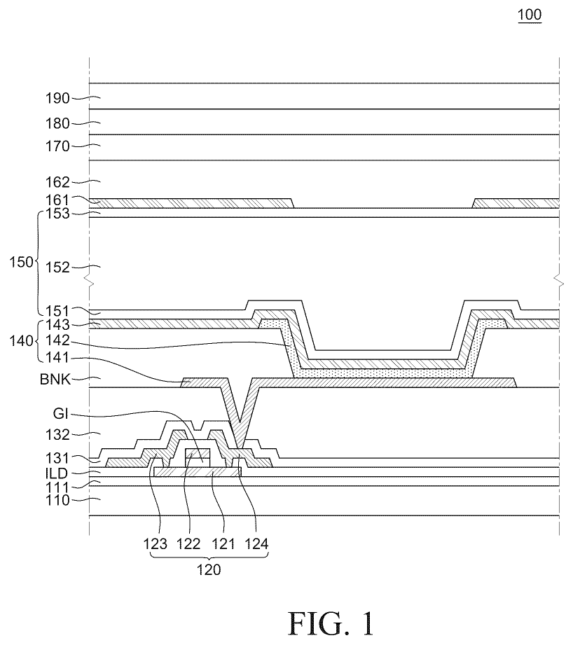

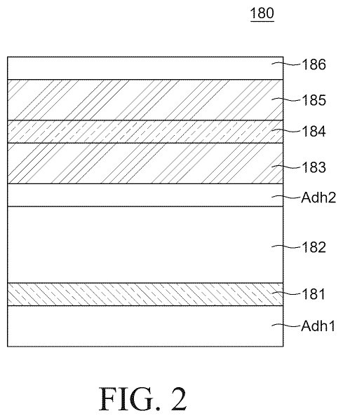

FIG. 1 is a cross-sectional view of a display device according to an embodiment of the present disclosure. FIG. 2 is a cross-sectional view of a polarizer according to an embodiment of the present disclosure.

The display device 100 according to the present disclosure includes a substrate 110, a thin film transistor 120, a passivation layer 131, a lower planarization layer 132, a light emitting diode 140, an encapsulation layer 150, a touch electrode 161, a gas blocking layer 170, a polarizer 180, and a cover member 190.

The substrate 110 supports elements which configure the display device 100. The substrate 110 may be formed of an insulating material. For example, the substrate 110 may be a glass substrate or may be formed of a polymer material. For example, the polymer may be selected from polyethylene terephthalate or polyimide, but is not limited thereto. The substrate 110 may be configured as a single layer or a multi-layered structure.

The substrate 110 includes areas defined as an active area and a non-active area. The active area is an area in which an image is displayed. In the active area, a plurality of sub pixels which displays images and a driving circuit for driving the plurality of sub pixels may be disposed. Each of the plurality of sub pixels is an individual unit which emits light and a light emitting diode 140 may be disposed in each of the plurality of sub pixels. In FIGS. 1-2, for the convenience of description, only one sub pixel is illustrated, but is not limited thereto.

Each of the plurality of sub pixels may be selected from a red sub pixel, a green sub pixel, a blue sub pixel, and a white sub pixel, but is not limited thereto. The driving circuit may include various transistors, storage capacitors, and wiring lines for driving the plurality of sub pixels. For example, the driving circuit may be configured by various components, such as a driving transistor, a switching transistor, a sensing transistor, a storage capacitor, a gate line, and a data line, but is not limited thereto.

The non-active area is an area which is disposed so as to enclose the active area and does not actually display images. In the non-active area, various wiring lines and driving ICs for driving a sub pixel disposed in the active area are disposed. For example, in the non-active area, various driving integrated circuits (ICs), such as a gate driver IC and a data driver IC, may be disposed, but are not limited thereto.

A buffer layer 111 may be disposed on the substrate 110. The buffer layer 111 protects the thin film transistor 120 and the light emitting diode 140 from moisture, external air, and foreign materials permeating from the outside. Further, the buffer layer 111 may suppress the change of the characteristic of the thin film transistor caused by hydrogen or a foreign material which is diffused to the substrate 110 during a forming process of a thin film transistor. The buffer layer 111 may be formed of an inorganic insulating material. For example, the buffer layer 111 may be formed of a material selected from a silicon oxide film, a silicon nitride film, or a silicon oxynitride film, but is not limited thereto. The buffer layer 111 may be formed as a single layer or a multi-layered structure. For example, the buffer layer 111 may be formed by a multi-layered structure in which a silicon oxide film and a silicon nitride film are laminated, but is not limited thereto.

The thin film transistor 120 is disposed on the buffer layer 111. The thin film transistor 120 includes an active layer 121, a gate electrode 122, a source electrode 123, and a drain electrode 124.

The active layer 121 is disposed on the buffer layer 111. The active layer 121 may be formed of an oxide semiconductor material or polycrystalline silicon. When the active layer 121 is formed of an oxide semiconductor material, a shield pattern may be further formed below the active layer 121. The shield pattern suppresses the active layer 121 which is formed of the oxide semiconductor from being damaged due to the ultraviolet ray. When the active layer 121 is formed of polycrystalline silicon, impurities may be doped on both edges of the active layer 121.

A gate insulating film GI which is formed of an insulating material is disposed on the active layer 121. The gate insulating film GI may be formed of a material selected from a silicon oxide film, a silicon nitride film, and a silicon oxynitride film, but is not limited thereto. Even though in FIG. 1, it is illustrated that the gate insulating film GI is disposed only in an area which overlaps the gate electrode 122, it is not limited thereto. The gate insulating film GI may be formed on the entire surface of the substrate 110.

The gate electrode 122 which is formed of a conductive material, such as metal, may be disposed on the gate insulating film GI. The gate electrode 122 is disposed so as to overlap a channel region of the active layer 121. For example, the gate electrode 122 may be configured by copper (Cu), aluminum (Al), molybdenum (Mo), nickel (Ni), titanium (Ti), chrome (Cr), or an alloy thereof, but is not limited thereto.

An interlayer insulating film ILD which is formed of an insulating material is substantially formed on the entire surface of the substrate 110 above the gate electrode 122. For example, the interlayer insulating film ILD may be formed of an inorganic insulating material, such as a silicon oxide film, a silicon nitride film, and a silicon oxynitride film, or an organic insulating material, such as photo acryl or benzocyclobutene, but is not limited thereto.

The interlayer insulating film ILD has a contact hole which exposes both side top surfaces of the active layer 121. When the gate insulating film GI is substantially formed on the entire surface of the substrate 110, the contact hole may also be formed in the gate insulating film GI. A source electrode 123 and a drain electrode 124 which are formed of a conductive material, such as metal are formed above the interlayer insulating film ILD. For example, the source electrode 123 and the drain electrode 124 may be configured by copper (Cu), aluminum (Al), molybdenum (Mo), nickel (Ni), titanium (Ti), chrome (Cr), or an alloy thereof, but are not limited thereto. The source electrode 123 and the drain electrode 124 are disposed to connect both sides of the active layer 121 through the contact hole of the interlayer insulating film ILD.

In FIG. 1, only one thin film transistor 120 is illustrated, but it is not limited thereto and a switching thin film transistor, a storage capacitor, or the like may be further disposed.

The passivation layer 131 is disposed on the thin film transistor 120 to protect the thin film transistor. For example, the passivation layer 131 may suppress the deterioration of the thin film transistor 120 due to external moisture or oxygen. For example, the passivation layer 131 may be formed of an inorganic insulating material, such as a silicon oxide film or a silicon nitride film, but is not limited thereto.

A lower planarization layer 132 is disposed on the passivation layer 131. The lower planarization layer 132 may planarize a top surface of the thin film transistor 120 and protect the thin film transistor 120 from external shocks. For example, the lower planarization layer 132 may be formed of an organic insulating material, such as polyimide or photo acryl, but is not limited thereto.

The passivation layer 131 and the lower planarization layer 132 may include a contact hole which electrically connects the source electrode 123 or the drain electrode 124, and the anode 141.

The light emitting diode 140 is disposed on the lower planarization layer 132. The light emitting diode 140 includes an anode 141, an organic emission layer 142, and a cathode 143.

The anode 141 is disposed on the lower planarization layer 132. The anode 141 is electrically connected to the drain electrode 124 of the thin film transistor 120 by means of a contact hole of the passivation layer 131 and the lower planarization layer 132. However, it is not limited thereto and the anode 141 may be electrically connected to the source electrode 123 of the thin film transistor 120.

The anode 141 may be formed of a conductive material having a high work function to supply holes to the organic emission layer 142. For example, the anode 141 may include a transparent conductive material such as indium tin oxide (ITO) and indium zinc oxide (IZO), but is not limited thereto. The anode 141 may be formed as a single layer or a multi-layered structure. When the light emitting diode 140 is implemented as a top emission type, the anode 141 may include a reflection layer which reflects light emitted from the organic emission layer 142 toward the cathode 143. The reflective layer may include a material having an excellent reflectivity, such as aluminum (Al), or silver (Ag), but is not limited thereto. For example, the anode 141 may be formed with a triple-layered structure in which indium tin oxide (ITO), silver (Ag), and indium tin oxide (ITO) are laminated, but is not limited thereto.

A bank BNK is disposed on the lower planarization layer 132 and the anode 141. The bank BNK is disposed on the lower planarization layer 132 so as to expose at least a part of the anode 141. That is, the bank BNK may be disposed on the lower planarization layer 132 so as to cover an edge of the anode 141. The bank BNK is an insulating layer disposed between the plurality of sub pixels to divide the plurality of sub pixels. The bank BNK may be formed of an organic insulating material. For example, the bank BNK may be formed of polyimide, acryl, or benzocyclobutene (BCB) resin, but it is not limited thereto.

The organic emission layer 142 is disposed on the anode 141. The organic emission layer 142 may be an organic layer which emits light having a specific color. The organic emission layer 142 may be patterned so as to correspond to each of the plurality of sub pixels. However, the present disclosure is not limited thereto. As another example, the organic emission layer 142 may be formed as one layer which is continuous over the entire active area.

The organic emission layer 142 may further selectively include various layers, such as a hole transport layer, a hole injection layer, a hole blocking layer, an electron injection layer, an electron blocking layer, or an electron transport layer, as needed.

The cathode 143 is disposed on the organic emission layer 142. The cathode 143 may be formed as one layer which is continuous over the entire active area. That is, the cathode 143 may be a common layer which is commonly formed in the plurality of sub pixels. The cathode 143 supplies electrons to the organic emission layer 142 so that the cathode may be formed of a conductive material having a low work function. For example, the cathode 143 may be formed of a transparent conductive material such as indium tin oxide (ITO) or indium zinc oxide (IZO), or a metal such as magnesium (Mg) or silver (Ag), or an alloy including the metal, and may further include a metal doping layer, but is not limited thereto.

A capping layer may be further disposed on the cathode 143. The capping layer suppresses deterioration of the cathode 143. Further, the capping layer reduces loss of light which is emitted from the organic emission layer 142 to be repeatedly reflected between the anode 141 and the cathode 143 to improve the luminous efficiency and reduce the power consumption.

The encapsulation layer 150 is disposed on the light emitting diode 140. The encapsulation layer 150 may be disposed over the active area and the non-active area. The encapsulation layer 150 planarizes a top surface of the light emitting diode 140. Further, the encapsulation layer 150 protects the light emitting diode 140 from moisture or foreign materials permeating from the outside of the display device 100. Further, the encapsulation layer 150 may protect the light emitting diode 140 from external shocks. For example, the encapsulation layer 150 may have a triple-layered structure including a first inorganic encapsulation layer 151, an organic encapsulation layer 152, and a second inorganic encapsulation layer 153, but is not limited thereto. The first inorganic encapsulation layer 151 is disposed on the cathode 143, the organic encapsulation layer 152 is disposed on the first inorganic encapsulation layer 151, and the second inorganic encapsulation layer 153 is disposed on the organic encapsulation layer 152.

The first inorganic encapsulation layer 151 is disposed on the cathode 143 to suppress the permeation of the moisture or oxygen and suppress the oxidation of the cathode 143. For example, the first inorganic encapsulation layer 151 may be formed of an inorganic insulating material, such as a silicon nitride film, a silicon oxide film, a silicon oxynitride film, or an aluminum oxide film, but is not limited thereto.

The organic encapsulation layer 152 is disposed on the first inorganic encapsulation layer 151 to planarize the surface. The organic encapsulation layer 152 is formed to be thicker than the first inorganic encapsulation layer 151. Therefore, the organic encapsulation layer 152 may be a foreign material cover layer which covers foreign materials generated during the process. For example, the organic encapsulation layer 152 may be formed of an organic insulating material, such as silicon oxy carbon, acrylic resin, or epoxy resin, but is not limited thereto.

The second inorganic encapsulation layer 153 is disposed on the organic encapsulation layer 152 to suppress the permeation of the moisture or oxygen. The second inorganic encapsulation layer 153 suppresses permeation of moisture or oxygen from the outside to the light emitting diode 140. For example, the second inorganic encapsulation layer 153 may be formed of an inorganic insulating material, such as a silicon nitride film, a silicon oxide film, a silicon oxynitride film, or an aluminum oxide film, but is not limited thereto.

Touch sensor units 161 and 162 are disposed on the encapsulation layer 150 to provide a touch sensing function. The touch sensor units 161 and 162 are configured to include a plurality of touch electrodes 161 and the upper planarization layer 162. The plurality of touch electrodes 161 is electrodes which sense the touch input. Even though it is not illustrated in FIG. 1, the plurality of touch electrodes 161 is configured by a sensing electrode and a driving electrode and senses a change in a capacitance between the sensing electrode and the driving electrode to detect a touch coordinate. The plurality of touch electrodes 161 may be disposed on the encapsulation layer 150 so as to overlap the bank BNK which is a non-emission area.

The touch sensor units 161 and 162 may be directly disposed on the encapsulation layer 150 without a separate adhesive member, but are not limited thereto. The touch sensor units 161 and 162 may be bonded onto the encapsulation layer 150 through an adhesive member as needed.

The upper planarization layer 162 covers a step caused by the plurality of touch electrodes 161 to planarize a top surface. Further, the upper planarization layer 162 protects the touch electrode 161 from the external shocks. For example, the upper planarization layer 162 may be formed of a transparent resin, such as acrylic resin, siloxane-based resin, polyimide-based resin, polyamide-based resin, cycloolefin-based resin, fluoro-based resin, photoacryl, benzocyclobutene, and polyamide, but is not limited thereto.

The gas blocking layer 170 is disposed on the touch sensor units 161 and 162. The gas blocking layer 170 blocks outgas generated from layers formed with an organic material which is disposed below the gas blocking layer 170. For example, components such as photo initiators or additives, of the upper planarization layer 162, the organic encapsulation layer 152, and the like which are formed of an organic material are volatilized or decomposed to generate outgas. When such outgas permeates the polarizer 180 located above, films which configure the polarizer 180 are deteriorated to cause discoloration, such as reddish, and degradation of the transmittance.

The gas blocking layer 170 is located between the touch sensor units 161 and 162 and the polarizer 180 and is disposed to be in direct contact with the bottom surface of the polarizer 180. Therefore, the gas blocking layer 170 blocks the outgas which is generated when the organic material layer, such as the upper planarization layer 162 or the organic encapsulation layer 152, is volatilized or decomposed under the high temperature/high humidity condition.

For example, the gas blocking layer 170 has a high curing rate of 90% or higher. In this case, the outgas generated from layers disposed below the gas blocking layer 170 may be effectively suppressed from permeating the polarizer 180.

The gas blocking layer 170 may include acrylic resin. For example, the gas blocking layer 170 includes an acrylic resin cured by including an acrylate-based monomer and a urethane acrylate oligomer. The acrylic resin cured by including an acrylate-based monomer and a urethane acrylate oligomer may have a higher curing rate than that of an acrylic resin which is cured without including the urethane acrylate oligomer. Therefore, the acrylic resin cured by including an acrylate-based monomer and a urethane acrylate oligomer has a high curing rate of 90% or higher to serve as the gas blocking layer 170. For example, a curing product of an acrylate-based monomer may have a curing rate of 60%, and a curing product cured by including an acrylate-based monomer and a urethane acrylate oligomer under the same curing condition may have a curing rate of 97% or higher.

For example, the acrylate-based monomer may be one or more types selected from methyl methacrylate, hydroxyalkyl acrylate, glycidyl methacrylate, multifunctional methacrylate, cyclopropyl (meth) acrylate, and cyclohexyl (meth) acrylate, but is not limited thereto. For example, the urethane acrylate oligomer may be one or more types selected from aromatic urethane acrylate, urethane methacrylate, multifunctional urethane acrylate with two or more functional groups, and multifunctional hyperbranched urethane acrylate, but is not limited thereto.

In order to form the acrylic resin having a high curing rate, during the photo curing, an exposure amount is increased or the curing process is performed twice or more to form the gas blocking layer 170. For example, a high curing rate may be achieved by primarily curing a composition including an acrylate-based monomer and a urethane acrylate oligomer and then additionally performing secondary curing. For example, the primary curing and the secondary curing may be independently performed by a method which is selected from the thermal curing and photo-curing methods. For example, when a composition including an acrylate-based monomer and a urethane acrylate oligomer is primarily cured with UV and then additionally thermally cured, the curing rate is increased by 5% or higher as compared with an example that performs only the UV curing.

As another example, a crosslinking agent may be added to increase the curing rate. For example, the gas blocking layer 170 may include an acrylic resin cured by including an acrylate-based monomer, a urethane acrylate oligomer, and a multifunctional acrylate-based crosslinking agent. In this case, the acrylic resin is crosslinked by the multifunctional acrylate-based crosslinking agent to achieve the high curing rate.

For example, the multifunctional acrylate-based crosslinking agent may be selected from pentaerythritol triacrylate, trimethylolpropane triacrylate, or the like, but is not limited thereto.

The polarizer 180 is disposed on the gas blocking layer 170. The polarizer 180 may have various combinations according to a requested optical characteristic. Hereinafter, the polarizer 180 will be described in detail with reference to FIG. 2. It should be noted that the polarizer 180 is not limited to the configuration illustrated in FIG. 2.

The polarizer 180 includes a first adhesive layer Adh1 at the bottom. The polarizer 180 may be bonded onto the gas blocking layer 170 by the first adhesive layer Adh1. For example, the first adhesive layer Adh1 may be selected from an optical clear adhesive (OCA), optical clear resin (OCR), and a pressure sensitive adhesive (PSA), but is not limited thereto.

The polarizer 180 includes a polarization film 184. The polarization film 184 transmits only linearly polarized light in a predetermined direction. Specifically, the polarization film 184 absorbs linearly polarized light parallel to an absorption axis and transmits linearly polarized light which is perpendicular to the absorption axis, that is, parallel to a transmission axis. For example, the polarization film 184 may be formed of poly vinyl alcohol (PVA) dyed with iodine ions or dichroic dyes to be stretched.

Polyvinyl alcohol may be deformed into polyene in a high temperature/high humidity environment. Specifically, in a high temperature/high humidity environment, iodine dyed on polyvinyl alcohol serves as a catalyst to change polyvinyl alcohol into polyene. In order to minimize or at least reduce this phenomenon, the polarization film 184 may further include a crosslinking agent which crosslinks the polyvinyl alcohol and a thermal stabilizer.

As described above, the acidic outgas generated from the organic material layer below the polarizer 180 reacts with the moisture to form hydrogen ions. The polyvinyl alcohol reacts with hydrogen ions to form polyene. When the polyvinyl alcohol is deformed into the polyene, discoloration, such as reddish, occurs and the transmittance may be degraded. However, in the display device 100 according to the embodiment of the present disclosure, the outgas may be blocked by the gas blocking layer 170 disposed below the polarizer 180. Therefore, the polyvinyl alcohol of the polarization film 184 may be suppressed from being deformed into the polyene.

A base film 183 may be disposed below the polarization film 184. The base film 183 supports the polarization film 184. For example, the base film 183 may be formed of a material selected from acrylic resin and polyethylene terephthalate, but is not limited thereto.

A protection layer 185 which protects the polarization film 184 from external moisture, oxygen, or foreign materials may be disposed above the polarization film 184. For example, the protection layer 185 may be formed of triacetylcellulose, cyclic olefin polymer, polycarbonate, acryl, or polyethylene terephthalate, but is not limited thereto.

A hard coating layer 186 may be further disposed above the protection layer 185 to protect the polarization film 184 from external shocks or scratches. For example, the hard coating layer 186 may be formed of a material selected from a urethane resin or a silicon resin, but is not limited thereto.

The polarizer 180 may further include at least one anti-reflection film to lower a reflectance of external light while maintaining a high emission efficiency of light emitted from the light emitting diode 140. For example, the polarizer 180 may include one or more types selected from a positive-C plate (+C plate) 181 and a neutral density filter 182, as the anti-reflection film. Even though in FIG. 2, it is illustrated that both the positive-C plate 181 and the neutral density filter 182 are included, the present disclosure is not limited thereto.

The +C plate 181 is a uniaxial retardation film, and may be a film in which the refractive index in the x-direction and the refractive index in the y-direction are the same, and the refractive index in the z-direction may be larger than the refractive indexes in the x-direction and the y-direction. By including the +C plate, reflection of external light not only in the front direction, but also in the lateral direction may be suppressed.

The neutral density filter 182 constantly reduces a transmission amount of light in a visible ray wavelength band. For example, the neutral density filter 182 constantly reduces a transmission amount of light with the wavelength in the range of 380 nm to 780 nm to lower a reflectance of the external light.

A second adhesive layer Adh2 may be disposed between the base film 183 and the neutral density filter 182. Therefore, the anti-reflection films 181 and 182 may be bonded to the base film 183 by the second adhesive layer Adh2. For example, the second adhesive layer Adh2 may be selected from an optical clear adhesive (OCA), optical clear resin (OCR), and a pressure sensitive adhesive (PSA), but is not limited thereto.

Optionally, the polarizer 180 may further include at least one retardation film between the anti-reflection films 181 and 182 and the polarization film 184 as needed. For example, the retardation film may include one or more types selected from a quarter (λ/4) wave plate (QWP) and a half (λ/2) wave plate (HWP).

It is noted that the polarizer 180 illustrated in FIG. 2 is illustrated for the convenience of description and it is not limited thereto. As another example, the polarizer 180 may have a structure in which the first adhesive layer, the +C plate, the λ/4 wave plate, the second adhesive layer, the polarization film, and the base film (and/or the protection layer) are laminated in this order. As needed, the anti-reflection film may be optionally omitted. For example, the polarizer 180 may have a structure in which the λ/4 wave plate, the λ/2 wave plate, the polarization film, and the base film (and/or the protection layer) are laminated in this order.

The cover member 190 is disposed on the polarizer 180. The cover member 190 protects the display device 100 from the outside air and the external shocks. For example, the cover member 190 may be selected from the cover glass or the cover film.

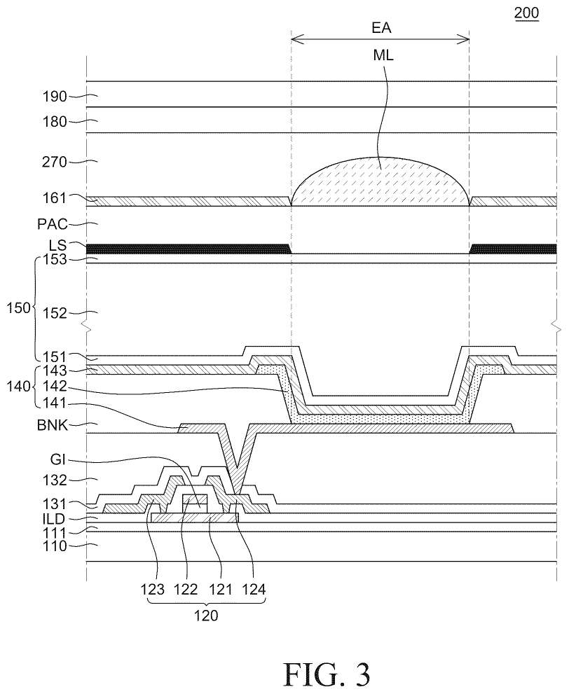

FIG. 3 is a cross-sectional view of a display device according to another embodiment of the present disclosure. A display device 200 illustrated in FIG. 3 includes a substrate 110, a thin film transistor 120, a passivation layer 131, a lower planarization layer 132, a light emitting diode 140, an encapsulation layer 150, a light shielding pattern LS, an optical gap layer PAC, a touch electrode 161, a plurality of lenses ML, a gas blocking layer 270, a polarizer 180, and a cover member 190. The display device 200 illustrated in FIG. 3 is substantially the same as the display device 100 described in FIGS. 1 and 2 except that a light shielding pattern LS, an optical gap layer PAC, and a plurality of lenses ML are further provided and the gas blocking layer 270 has a different placement structure. Therefore, a description of repeated components will be omitted.

Referring to FIG. 3, the display device 200 includes the light shielding pattern LS, the optical gap layer PAC, and the plurality of lenses ML, which control light emitted from the light emitting diode 140 to improve a light emission efficiency and reduce the viewing angle.

The light shielding pattern LS is disposed on the encapsulation layer 150. The light shielding pattern LS is disposed so as to be in contact with the second inorganic encapsulation layer 153. The light shielding pattern LS is disposed so as to overlap a bank BNK corresponding to the non-emission area of the light emitting diode 140. By doing this, light which travels from the light emitting diode 140 of one sub pixel toward a light emitting diode 140 of an adjacent sub pixel is blocked. Therefore, light is not emitted through an area other than the emission area EA of each sub pixel so that the viewing angle may be reduced. For reference, the emission area EA may be defined as an area which is not covered by the bank BNK to be exposed.

The optical gap layer PAC is disposed on the light shielding pattern LS. The optical gap layer PAC ensures an optical gap between the light emitting diode 140 and the lens ML to improve a front light emission efficiency of light emitted from the light emitting diode 140. Further, the optical gap layer PAC removes the step of the light shielding pattern LS to planarize the upper portion of the light shielding pattern LS. For example, the optical gap layer PAC may be formed of transparent resin, such as acrylic resin, but is not limited thereto.

The touch electrode 161 is disposed on the optical gap layer PAC. The touch electrode 161 may be disposed so as to overlap the light shielding pattern LS.

Each of the plurality of lenses ML is disposed on the optical gap layer PAC. Each of the plurality of lenses ML is disposed so as to correspond to the emission area EA of the light emitting diode 140 included in each of the plurality of sub pixels. Each of the plurality of lenses ML is disposed so as to overlap the emission area EA to improve the front light emission efficiency of light emitted from the light emitting diode 140. For example, a cross-section of each of the plurality of lenses ML may have a semi-circular shape, but is not limited thereto.

In the display device 100 of FIGS. 1 and 2, the upper planarization layer 162 is disposed so as to cover the touch electrode 161 and the gas blocking layer 170 is disposed on the upper planarization layer 162. In contrast, the display device 200 illustrated in FIG. 3 does not include the upper planarization layer 162 and instead, the gas blocking layer 270 is disposed so as to cover the touch electrode 161 and the plurality of lenses ML.

That is, the gas blocking layer 270 removes the step caused by the touch electrode 161 and the plurality of lenses ML to planarize upper portions of the touch electrode 161 and the plurality of lenses ML. Further, the gas blocking layer 270 protects components that are below the gas blocking layer 270 from external shocks.

The gas blocking layer 270 has a high curing rate of 90% or higher. In this case, the outgas generated from layers disposed below the gas blocking layer 270 is effectively suppressed from permeating the polarizer 180.

The gas blocking layer 270 may include acrylic resin. For example, the gas blocking layer 270 may include an acrylic resin cured by including an acrylate-based monomer and a urethane acrylate oligomer. Therefore, the acrylic resin cured by including an acrylate-based monomer and a urethane acrylate oligomer has a high curing rate of 90% or higher to serve as the gas blocking layer 270.

Further, a crosslinking agent may be added to increase the curing rate. For example, the gas blocking layer 270 may include an acrylic resin cured by including an acrylate-based monomer, a urethane acrylate oligomer, and a multifunctional acrylate-based crosslinking agent. In this case, the acrylic resin is crosslinked by the multifunctional acrylate-based crosslinking agent to achieve the high curing rate.

Specific characteristics of the acrylate-based monomer, the urethane acrylate oligomer, and the multifunctional acrylate-based crosslinking agent are the same as described above, so that a redundant description will be omitted.

The plurality of lenses ML and the gas blocking layer 270 may have different refractive indexes. For example, the refractive index of the gas blocking layer 270 may be lower than a refractive index of the plurality of lenses ML. Therefore, the light emitted to the outside of the display device 200 may be collected by means of the plurality of lenses ML.

The gas blocking layer 270 may include fluoro resin to have a refractive index lower than that of the plurality of lenses ML. For example, the gas blocking layer 270 includes one or more types of resins selected from an acrylic resin cured by including an acrylate-based monomer and urethane acrylate oligomer and fluoro resin. The fluoro resin has a lower refractive index than the acrylic resin. Therefore, as in the display device 200 of FIG. 3, when the gas blocking layer 270 is disposed so as to cover the plurality of lenses ML, the gas blocking layer 270 may include the fluoro resin to more effectively collect the light.

For example, the gas blocking layer 270 may include a fluoro resin cured by including (per)fluoro(alkyl vinyl ether) and fluorinated polyol. For example, (per)fluoro(alkyl vinyl ether) may be selected from (per)fluoro(propyl vinyl ether), etc., but is not limited thereto. For example, the fluorinated polyol may be selected from (per)fluoro polyester polyol, (per)fluoro alkandiol, and the like, but is not limited thereto.

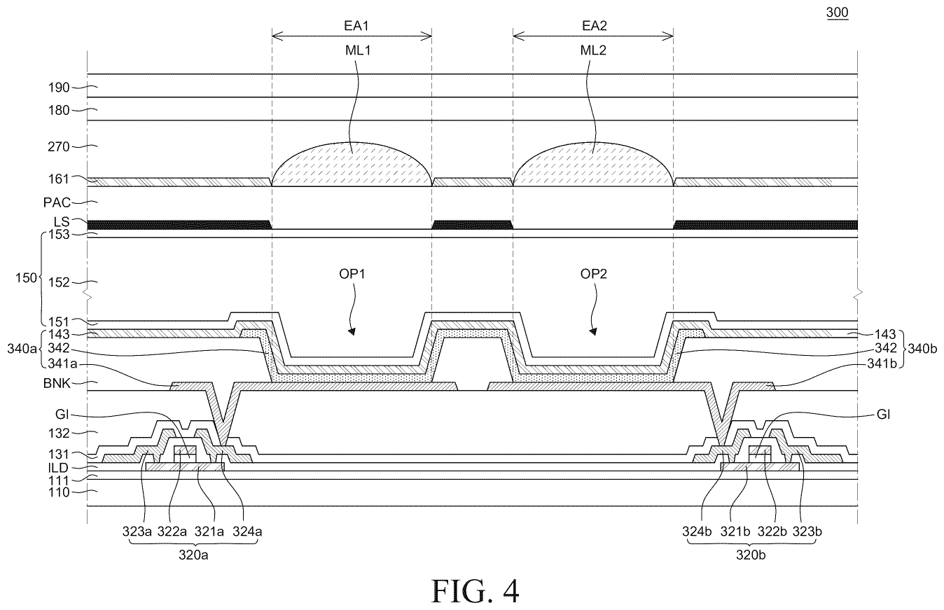

FIG. 4 is a cross-sectional view of a display device according to still another embodiment of the present disclosure. Referring to FIG. 4, a display device 300 includes a substrate 110, thin film transistors 320a and 320b, a passivation layer 131, a lower planarization layer 132, light emitting diodes 340a and 340b, an encapsulation layer 150, a light shielding pattern LS, an optical gap layer PAC, a touch electrode 161, a plurality of lenses ML1 and ML2, a gas blocking layer 270, a polarizer 180, and a cover member 190. The display device 300 illustrated in FIG. 4 is substantially the same as the display device 200 described in FIG. 3 except for placement structures of the thin film transistors 320a and 320b, the light emitting diodes 340a and 340b, and the plurality of lenses ML1 and ML2. Therefore, a description of repeated components will be omitted.

In the display device 300, one sub pixel includes a first light emitting diode 340a and a second light emitting diode 340b. Further, the first light emitting diode 340a is electrically connected to a first thin film transistor 320a and the second light emitting diode 340b is electrically connected to a second thin film transistor 320b.

First, the first thin film transistor 320a and the second thin film transistor 320b will be described in detail.

A first active layer 321a and a second active layer 321b are formed on the buffer layer 111, respectively. The first active layer 321a and the second active layer 321b may be independently formed of an oxide semiconductor material or polycrystalline silicon, respectively.

A first gate electrode 322a is disposed on the first active layer 321a so as to overlap a channel region of the first active layer 321a with a gate insulating film GI therebetween. A second gate electrode 322b is disposed on the second active layer 321b so as to overlap a channel region of the second active layer 321b with a gate insulating film GI therebetween. For example, each of the first gate electrode 322a and the second gate electrode 322b may be configured by copper (Cu), aluminum (Al), molybdenum (Mo), nickel (Ni), titanium (Ti), chrome (Cr), or an alloy thereof, but is not limited thereto.

An interlayer insulating film ILD which is formed of an insulating material is substantially formed on the entire surface of the substrate 110, above the first gate electrode 322a and the second gate electrode 322b. The interlayer insulating film ILD has a contact hole which exposes both side top surfaces of each of the first active layer 321a and the second active layer 321b.

A first source electrode 323a, a first drain electrode 324a, a second source electrode 323b, and a second drain electrode 324b which are formed of a conductive material, such as metal, are disposed above the interlayer insulating film ILD. The first source electrode 323a and the first drain electrode 324a are in contact with both sides of the first active layer 321a through a contact hole of the interlayer insulating film ILD and the second source electrode 323b and the second drain electrode 324b are in contact with both sides of the second active layer 321b through the contact hole of the interlayer insulating film ILD.

For example, each of the first source electrode 323a, the first drain electrode 324a, the second source electrode 323b, and the second drain electrode 324b may be configured by copper (Cu), aluminum (Al), molybdenum (Mo), nickel (Ni), titanium (Ti), chrome (Cr), or an alloy thereof, but is not limited thereto.

The first active layer 321a, the first gate electrode 322a, the first source electrode 323a, and the first drain electrode 324a form the first thin film transistor 320a. The second active layer 321b, the second gate electrode 322b, the second source electrode 323b, and the second drain electrode 324b form the second thin film transistor 320b.

A passivation layer 131 and a lower planarization layer 132 are sequentially laminated on the first thin film transistor 320a and the second thin film transistor 320b. The passivation layer 131 and the lower planarization layer 132 may include a contact hole for electrically connecting the first source electrode 323a or the first drain electrode 324a to the first anode 341a and a contact hole for electrically connecting the second source electrode 323b or the second drain electrode 324b to the second anode 341b, respectively.

The first light emitting diode 340a and the second light emitting diode 340b are disposed on the lower planarization layer 132. The first light emitting diode 340a includes a first anode 341a, an organic emission layer 342, and a cathode 143 and the second light emitting diode 340b includes a second anode 341b, an organic emission layer 342, and a cathode 143.

Each of the first anode 341a and the second anode 341b is disposed on the lower planarization layer 132. The first anode 341a may be electrically connected to the first drain electrode 324a of the first thin film transistor 320a through the contact holes of the passivation layer 131 and the lower planarization layer 132. The second anode 341b may be electrically connected to the second drain electrode 324b of the second thin film transistor 320b through the contact holes of the passivation layer 131 and the lower planarization layer 132.

For example, each of the first anode 341a and the second anode 341b may be formed of a transparent conductive material, such as indium tin oxide (ITO) or indium zinc oxide (IZO), but is not limited thereto.

A bank BNK is disposed on the lower planarization layer 132, the first anode 341a, and the second anode 341b. The bank BNK is disposed on the lower planarization layer 132 so as to expose at least a part of each of the first anode 341a and the second anode 341b. That is, the bank BNK may be disposed on the lower planarization layer 132 so as to cover an edge of each of the first anode 341a and the second anode 341b. Therefore, the bank BNK includes a first opening OP1 which exposes the first anode 341a and a second opening OP2 which exposes the second anode 341b. Accordingly, the bank BNK not only may separate the plurality of sub pixels, but also separate the first light emitting diode 340a and the second light emitting diode 340b included in each of the plurality of sub pixels, from each other. An area corresponding to the first anode 341a which is exposed without being covered by the bank BNK may be defined as a first emission area EA1 and an area corresponding to the second anode 341b which is exposed without being covered by the bank BNK may be defined as a second emission area EA2. That is, the first emission area EA1 overlaps the first opening OP1 and the second emission area EA2 overlaps the second opening OP2.

The organic emission layer 342 is formed above the first anode 341a and the second anode 341b which are exposed by the first opening OP1 and the second opening OP2 of the bank BNK. The organic emission layer 342 above the first anode 341a and the organic emission layer 342 above the second anode 341b are connected to each other to be integrally formed. However, these are not limited thereto and the organic emission layer 342 above the first anode 341a and the organic emission layer 342 above the second anode 341b may be separated from each other.

The cathode 143 is disposed on the organic emission layer 342. The cathode 143 may be formed as one layer which is continuous over the entire active area.

An encapsulation layer 150 is disposed on the first light emitting diode 340a and the second light emitting diode 340b and a light shielding pattern LS is disposed on the encapsulation layer 150. The light shielding pattern LS is disposed so as to overlap the bank BNK corresponding to the non-emission areas of the first light emitting diode 340a and the second light emitting diode 340b. That is, the light shielding pattern LS has an opening in a position corresponding to the first emission area EA1 and the second emission area EA2.

An optical gap layer PAC is disposed on the light shielding pattern LS to planarize an upper portion of the light shielding pattern LS. The touch electrode 161 is disposed on the optical gap layer PAC. The touch electrode 161 may be disposed so as to overlap the light shielding pattern LS.

Further, a first lens ML1 and a second lens ML2 are disposed on the optical gap layer PAC. The first lens ML1 is disposed so as to overlap the first emission area EA1 and the second lens ML2 is disposed so as to overlap the second emission area EA2.

The first lens ML1 is disposed in the first emission area EA1 to refract light from the first light emitting diode 340a to a specific direction. The second lens ML2 is disposed in the second emission area EA2 to refract light from the second light emitting diode 340b to a specific direction.

The first lens ML1 and the second lens ML2 may have different shapes. For example, the first lens ML1 may be a half-spherical lens and the second lens ML2 may be a half-cylindrical lens. Therefore, the light emitted from the first light emitting diode 340a is refracted at a specific angle by the first lens ML1 to be emitted and the light emitted from the second light emitting diode 340b is refracted at a specific angle which is different from that of the first lens ML1, by the second lens ML2 to be emitted. The first lens ML1 and the second lens ML2 limit the viewing angle in different directions, due to the different shapes of the first lens ML1 and the second lens ML2. Therefore, the first light emitting diode 340a and the second light emitting diode 340b are selectively driven to implement a wide viewing angle and a narrow viewing angle. For example, the first emission area EA1 in which the semi-spherical first lens ML1 is disposed may have a narrow viewing angle of 30 degrees or smaller in up, down, left, and right directions. The second emission area EA2 in which the semi-cylindrical second lens ML2 is disposed may have a narrow viewing angle of 30 degrees or smaller in a up and down direction and a wide viewing angle of 60 degrees or larger in a left and right direction. Accordingly, the up and down narrow field of view mode and the left and right narrow field of view mode may be implemented by driving the first light emitting diode 340a and the up and down narrow field of view mode and the left and right wide field of view mode may be implemented by driving the second light emitting diode 340b.

The display device 300 illustrated in FIG. 4 does not include the upper planarization layer 162 of the display device 100 of FIG, 1, but instead, include the gas blocking layer 270 so as to cover the touch electrode 161, the first lens ML1, and the second lens ML2.

The gas blocking layer 270 may have a refractive index which is different from the first lens ML1 and the second lens ML2. For example, the refractive index of the gas blocking layer 270 may be smaller than the refractive index of each of the first lens ML1 and the second lens ML2.

A polarizer 180 and a cover member 190 may be sequentially laminated on the gas blocking layer 270. The gas blocking layer 270, the polarizer 180, and the cover member 190 are the same as described above in FIGS. 1 to 3 so that a redundant description will be omitted.

Hereinafter, the effects of the present disclosure which has been described above will be described with reference to different embodiments. However, the following embodiments are set forth to illustrate the present disclosure, but the scope of the present disclosure is not limited thereto.

### Experimental Embodiment 1

A reliability test was conducted to find out the presence of a gas blocking layer and an effect difference according to a curing rate thereof. To this end, a sample with a configuration as listed in Table 1 was produced and the reliability test was conducted under a high temperature/high humidity (85° C./85%). During the reliability test, a sample was stored in the high temperature/high humidity, a time when the reddish was observed was recorded, and a level of the reddish was evaluated as high, medium, low, and N/A.

TABLE 1

| | Comparative | | |
|---|---|---|---|
| | Embodiment | Reference Embodiment | Embodiment 1 |
| Structure | Organic | Organic layer/gas | Organic layer/gas blocking |
| | layer/Polarizer/Cover | blocking layer with | layer with curing rate of |
| | glass | curing rate of | 90%/Polarizer/Cover glass |
| | | 85%/Polarizer/Cover | |
| | | glass | |
| Time when | After 420 hours | After 792 hours | — |
| reddish occurs | | | |
| Level of reddish | High | Medium | N/A |

Referring to Table 1, according to Comparative Embodiment in which the gas blocking layer is not included, it was confirmed that a high level of reddish was observed after 420 hours. In Reference Embodiment in which a gas blocking layer with a curing rate of 85% was provided between an organic material layer and a polarizer, it was confirmed that a level of reddish was lower than that of Comparative Embodiment, but the reddish was observed after 792 hours. In Embodiment 1 including a gas blocking layer with a curing rate of 90%, it was confirmed that the reddish did not occur during 1366 hours. That is, the gas blocking layer with a high curing rate of 90% or higher may suppress the outgas from permeating the polarizer. Accordingly, even though the outgas is generated from the organic layer under the high temperature/high humidity condition, the outgas is blocked to suppress discoloration or deformation of the polarizer.

### Experimental Embodiment 2

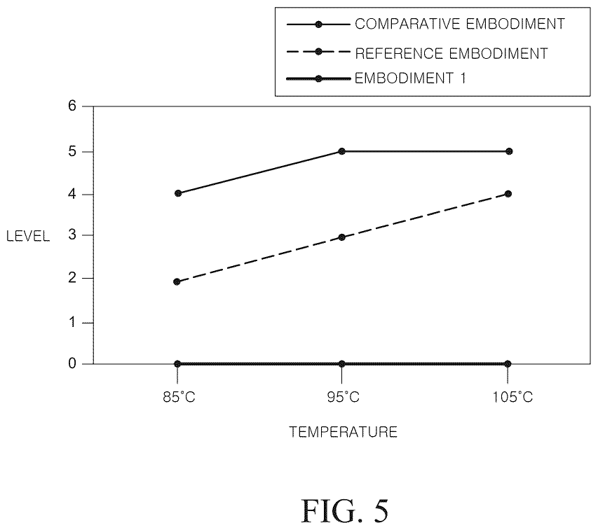

In order to find out the level of reddish according to a temperature of a specimen according to Comparative Embodiment, Reference Embodiment, and Embodiment 1, the specimen was stored for 500 hours under the conditions of 85° C., 95° C., and 105° C., respectively. After 500 hours, the level of reddish of the specimen was visually observed. The result is represented in FIG. 5. FIG. 5 is a graph illustrating a degree of occurrence of the reddish phenomenon according to a temperature of a specimen according to Comparative Embodiment, Reference Embodiment, and Embodiment 1, respectively according to one or more embodiments of the present disclosure. In FIG. 5, level 0 means that the reddish does not occur, level 1 means that reddish has occurred at a weak level, level 2 is a medium weak level of reddish, level 3 is a medium level of reddish, level 4 is a medium high level of reddish, and level 5 is a high level of reddish.

Referring to FIG. 5, it was confirmed that in Embodiment 1 including a gas blocking layer with a curing rate of 90%, the reddish has not occurred under the temperature conditions of 85° C., 95° C., and 105° C., respectively.

In contrast, it was confirmed that in Comparative Embodiment in which a gas blocking layer was not provided, the most severe reddish was visually observed. Reference Embodiment includes the gas blocking layer, but has a curing rate of 85% which is lower than that of Embodiment 1. Therefore, it was confirmed that the level of reddish was lower than that of Comparative Embodiment, but as the temperature was increased to 85° C., 95° C., and 105° C., the intensity of the reddish was sharply increased.

In summary, under the high temperature environment of 85° C. or higher, the outgas is generated from the organic layer to change the polyvinyl alcohol included in the polarizer into polyene, which results in the reddish to discolor the color of the specimen to red. Therefore, when the gas blocking layer is provided between the organic layer and the polarizer, the outgas is blocked to reduce the reddish. Further, when the gas blocking layer having a high curing rate of 90% is provided as in Embodiment 1, it is confirmed that the outgas is more effectively blocked to suppress the reddish.

The embodiments of the present disclosure can also be described as follows:

According to one or more embodiments of the present disclosure, an organic light emitting display device includes a substrate; a plurality of light emitting diodes disposed on the substrate; an encapsulation layer disposed so as to cover the plurality of light emitting diodes; a gas blocking layer disposed on the encapsulation layer; and a polarizer disposed on the gas blocking layer, and in which the gas blocking layer is disposed so as to be in direct contact with a bottom surface of the polarizer and has a curing rate of 90% or higher.

The organic light emitting display device may further comprise a plurality of touch electrodes disposed on the encapsulation layer, wherein the gas blocking layer may be disposed on the plurality of touch electrodes.

The organic light emitting display device may further comprise a planarization layer which is disposed between the encapsulation layer and the gas blocking layer to cover the plurality of touch electrodes.

The gas blocking layer may include acrylic resin cured by including an acrylate-based monomer and a urethane acrylate oligomer.

The gas blocking layer may include acrylic resin cured by further including a multifunctional acrylate-based crosslinking agent.

The polarizer may include an adhesive layer which is in contact with the gas blocking layer; at least one anti-reflection film disposed on the adhesive layer; a polarization film which is disposed on the anti-reflection film and includes polyvinyl alcohol; and a base film disposed on at least one surface of the polarization film.

The anti-reflection film may include one or more types selected from a +C plate (positive-C plate) and a neutral density filter.

The polarizer may further include at least one retardation film disposed between the anti-reflection film and the polarization film.

The retardation film may include one or more types selected from a quarter (λ/4) wave plate (QWP) and a half (λ/2) wave plate (HWP).

The organic light emitting display device may further include a plurality of lenses disposed between the plurality of touch electrodes so as to correspond to an emission area of the light emitting diode, and the gas blocking layer may be disposed so as to cover the plurality of lenses and the plurality of touch electrodes.

The organic light emitting display device may further include: a light shielding pattern disposed on the encapsulation layer so as to correspond to a non-emission area of the light emitting diode; and an optical gap layer disposed on the light shielding pattern, wherein the plurality of lenses and the plurality of touch electrodes may be disposed on the optical gap layer.

A refractive index of the gas blocking layer may be lower than a refractive index of the plurality of lenses.

A plurality of sub pixels may be defined on the substrate, each of the plurality of sub pixels may include a first light emitting diode and a second light emitting diode disposed on the substrate, and the plurality of lenses may include a first lens corresponding to an emission area of the first light emitting diode and a second lens corresponding to an emission area of the second light emitting diode.

The first lens may be a half-spherical lens and the second lens may be a half-cylindrical lens.

The gas blocking layer may include one or more types of resins selected from an acrylic resin cured by including an acrylate-based monomer and a urethane acrylate oligomer and a fluoro resin cured by including (per)fluoro(alkyl vinyl ether) and fluorinated polyol.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting display device, comprising:
a substrate;
a plurality of light emitting diodes on the substrate;
an encapsulation layer that covers the plurality of light emitting diodes;
a gas blocking layer on the encapsulation layer, the gas blocking layer having a curing rate of 90% or higher; and
a polarizer on the gas blocking layer, a bottom surface of the polarizer in direct contact with the gas blocking layer.

2. The organic light emitting display device according to claim 1, further comprising a plurality of touch electrodes on the encapsulation layer, wherein the gas blocking layer is on the plurality of touch electrodes.

3. The organic light emitting display device according to claim 2, further comprising a planarization layer between the encapsulation layer and the gas blocking layer, the planarization layer covers the plurality of touch electrodes.

4. The organic light emitting display device according to claim 1, wherein the gas blocking layer includes an acrylic resin cured by including an acrylate-based monomer and a urethane acrylate oligomer in the acrylic resin.

5. The organic light emitting display device according to claim 4, wherein the gas blocking layer includes the acrylic resin cured by further including a multifunctional acrylate-based crosslinking agent in the acrylic resin.

6. The organic light emitting display device according to claim 1, wherein the polarizer includes:
an adhesive layer in contact with the gas blocking layer;
at least one anti-reflection film on the adhesive layer;
a polarization film on the at least one anti-reflection film, the polarization film including a polyvinyl alcohol; and
a base film on at least one surface of the polarization film.

7. The organic light emitting display device according to claim 6, wherein the at least one anti-reflection film includes one or more types selected from a +C plate and a neutral density filter.

8. The organic light emitting display device according to claim 6, wherein the polarizer further includes at least one retardation film between the at least one anti-reflection film and the polarization film.

9. The organic light emitting display device according to claim 8, wherein the at least one retardation film includes one or more types selected from a quarter wave plate and a half wave plate.

10. The organic light emitting display device according to claim 2, further comprising a plurality of lenses between the plurality of touch electrodes, the plurality of lenses corresponding to an emission area of a light emitting diode of the plurality of light emitting diodes, and
the gas blocking layer covers the plurality of lenses and the plurality of touch electrodes.

11. The organic light emitting display device according to claim 10, further comprising:
a light shielding pattern on the encapsulation layer, the light shielding pattern corresponding to a non-emission area of the light emitting diode; and
an optical gap layer on the light shielding pattern,
wherein the plurality of lenses and the plurality of touch electrodes are on the optical gap layer.

12. The organic light emitting display device according to claim 10, wherein a refractive index of the gas blocking layer is lower than a refractive index of the plurality of lenses.

13. The organic light emitting display device according to claim 10, wherein a plurality of sub pixels are on the substrate, each of the plurality of sub pixels includes a first light emitting diode on the substrate and a second light emitting diode on the substrate, and the plurality of lenses include a first lens corresponding to an emission area of the first light emitting diode and a second lens corresponding to an emission area of the second light emitting diode.

14. The organic light emitting display device according to claim 13, wherein the first lens is a half-spherical lens, and the second lens is a half-cylindrical lens.

15. The organic light emitting display device according to claim 10, wherein the gas blocking layer includes one or more types of resins selected from an acrylic resin and a fluoro resin, the acrylic resin cured by including an acrylate-based monomer and a urethane acrylate oligomer in the acrylic resin, and the fluoro resin cured by including a (per)fluoro(alkyl vinyl ether) and a fluorinated polyol in the fluoro resin.
